(19) United States
(12) Patent Application Publication
(10) Pub. No.: US 2018/0238955 A1
(43) Pub. Date: Aug. 23, 2018

(54) System For The Standoff Detection Of Power Line Hazards And Means For Standoff Data Collection, Storage, And Dissemination

(71) Applicant: Connecticut Analytical Corporation, Bethany, CT (US)

(72) Inventors: Joseph J. Bango, New Haven, CT (US); Michael Dziekan, Bethany, CT (US)

(73) Assignee: Connecticut Analytical Corporation, Bethany, CT (US)

(21) Appl. No.: 15/882,133

(22) Filed: Jan. 29, 2018

Related U.S. Application Data
(63) Continuation-in-part of application No. 14/756,193, filed on Aug. 14, 2015, now Pat. No. 9,970,975.
(60) Provisional application No. 62/070,105, filed on Aug. 14, 2014.

(51) Int. Cl. G01R 31/08; G01R 15/18; G01R 19/02; G08B 21/02; G08G 1/005

(52) U.S. Cl. CPC G01R 31/085; G01R 15/186; G08G 1/005; G08B 21/02; G01R 19/02

(57) ABSTRACT

The disclosed invention mitigates unnecessary electric utility and first responder intervention in the event of a downed electrical cable that may not present a voltage hazard. The disclosed downed power line status indicator invention serves to protect the public while increasing the ability to repair lines damaged due to an unplanned natural calamity or other incident. In the preferred embodiment, the invention can capture the status of a downed line and if it is energized, provide a local visual and audible alarm of hazardous conditions to anyone in the vicinity of the downed line. In addition, the invention can generate a message or notification sent to the utility's operations center. In addition, the disclosed invention perch of the disclosed invention affords capability to capture, store, and disseminate data relating to natural or man-made disasters, RF transmissions, GPS and other navigational data, and for commercial data collection, storage, and dissemination.

### CROSS-REFERENCE APPLICATIONS

This application claims priority of application Ser. No. 14/756,193 filed 08-14-2015, Provisional 62/070,105 filed Aug. 14, 2014. This and all other extrinsic references referenced herein are incorporated by reference in their entirety.

This inventive subject matter in this application was made without government support

### FIELD OF THE INVENTION

This invention relates to the Field of systems for the Standoff Detection of Power Line Hazards and for systems that send a signal to a responsible repair center to inform the center of the location of the defect in the line. In addition, this invention relates to the collection of visual, audible, radio frequency, and other data for analysis, storage, and dissemination.

### BACKGROUND

The background description includes information that may be useful in understanding the present invention. It is not an admission that any of the information provided herein is prior art or relevant to the presently claimed invention, or that any publication specifically or implicitly referenced is prior art.

All publications herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

A first objective of the present invention is to solve the problem of providing a signal to a responsible repair center that will characterize the type of cable or power line that is down to enable a responsible repair center to accurately evaluate the defect and determine what repair service is necessary, if any.

### RELATED ART

The following description includes information that may be useful in understanding the present invention. It is not an admission that any of the information provided herein is prior art or relevant to the presently claimed invention, or that any publication specifically or implicitly referenced is prior art.

A prior Department of Homeland Security revealed the need for a power line status solution. Downed power lines exhibit many well-known characteristics. There is a significant change in the areas magnetic field or B field, depending on the potential difference between the line and the ground, there may be some corona or arcing. If there is corona or arcing, there will be current consumption and therefore a change in the thermal signature of the line with respect to the surroundings. Arcing/corona produce ozone, RF interference, ultraviolet, and ultrasonic emissions. Ambient conditions can accentuate or mitigate many of these effects, depending for example if the weather is dry or humid. The magnitude of the electrical potential determines whether many characteristic downed line signatures are present as well. A 120 VAC leg from a distribution transformer is less likely to arc than a 14.4 kV feeder to the distribution transformer. On the utility side, a downed line or lines may represent an unbalanced load and most certainly will result in a significant change in the transmission line reactance and power factor characteristics in contrast to the moment before the line was severed. There is likely significant spikes and noise on the line that will be present as well. As a result, there have been a number of approaches in the prior art that have been used to detect the downed line.

### SUMMARY OF THE INVENTION

The following discussion provides many example embodiments of the inventive subject matter including apparatus, systems, and methods. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

The disclosed invention teaches a fusion of technologies which include the employment of integrated circuits that provide signals that indicate a change in spatial attitude of a sudden break or slack in an electrical transmission line, with options for detecting and reporting the presence of a magnetic field and or an electric field. Visual and audible alerts are provided so that the lay public can be alerted to a power line hazard. In addition, through the use of a Smartphone application, preferably for an iPhone or Android, power line integrity status can be safely communicated visually or via radio frequency transmission by the disclosed invention to personnel isolated from the transmission line.

Various objects, features, aspects and advantages of the inventive subject matter will become more apparent from the following detailed description of preferred embodiments, along with the accompanying drawing figures in which like numerals represent like components.

It is a first object of the present invention is to reduce or eliminate unnecessary electric utility and first responder intervention in the event of a downed electrical cable that may not present a voltage hazard. Utilities are besieged by calls of downed wires, which may in fact be only telephone, cable TV, or other non-hazardous electrical or even fiber optic lines. Nevertheless, power utilities must consider all downed lines as live electrical carriers. Responding as such taxes a utilities ability to effect rapid overall system damage assessment and prolongs system restoration.

It is a second object of the invention to provide a downed line status indicator that will help the public near the defect to avoid danger and assist the responsible repair center in analyzing the defect so as to increase the ability of the responsible repair center to repair lines damaged due to an unplanned natural calamity or other incident. The status indicator includes the use of a short array of color coded LED that would alert the public with a light source and inform the public of the status and mode of the downed line. If the downed line is not energized, the disclosed invention provides a status both to the utility and to anyone in the vicinity of the fact that the line is not energized.

A third objective of the invention disclosed is to provide a warning as to a whether a power line is live, whether this represents high voltage before a distribution transformer, or line voltage from a distribution transformer.

It is a fourth objective of the invention to provide for detection of a fallen power line and to provide signal or signals that indicate if the power line is experiencing a load due to arcing or a corona. In other words, current detection is not enough; the presence of an electric field with the capability to pass current is detected. Earlier art has shown the loss of load or a change in the line voltage to indicate a possible problem on the line

Various objects, features, aspects and advantages of the inventive subject matter will become more apparent from the following detailed description of preferred embodiments, along with the accompanying drawing figures in which like numerals represent like components.

The following discussion provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

### BRIEF DESCRIPTION OF THE DRAWING

FIG. 1 shows a drawing of a block diagram of the preferred embodiment system, which includes a split ferrite core that can be enclosed like a clamshell around a transmission line through which an alternating current is flowing. The block diagram details how the different sections are arranged

FIG. 2 shows a drawing of how the preferred embodiment of the disclosed power transmission line monitor is physically attached to a power transmission line. Visual status LED lamps are located on the outside face of the monitor assembly and provide diagnostic features.

FIG. 3 shows a drawing of a perspective view of three parallel power line monitors, each being equipped with a sensor used by the invention.

FIG. 4 shows a drawing of the preferred embodiment of the disclosed invention located next to a roadway attached to power transmission lines.

FIG. 5 shows a schematic drawing of a spatial attitude sensor, which is part of the sensor package in FIG. 1. The spatial sensor is used to determine if any damage or tampering of the power line has transpired.

FIG. 6 shows a schematic drawing of the preferred embodiment of the disclosed inventions thermal sensing circuit, which is part of the sensor package in FIG. 1. The thermal sensing circuit is used to measure ambient temperature.

FIG. 7 shows a drawing of the preferred embodiment of the disclosed invention located next to a roadway, a typical location for power transmission lines. A small fire is shown in close proximity to the transmission lines.

FIG. 8 shows a drawing of a block diagram showing additional detail of a portion of what is contained in FIG. 1, specifically, the sensor package. Each individual sensor will have a unique address that allows the microcontroller to communicate individually to each sensor contained within the sensor package.

FIG. 9 shows a block diagram of a segment of the communication module illustrating the bluetooth communication module that will allow a smart phone with a proprietary app to remotely interrogate any power line monitor within range.

### DETAILED DESCRIPTION OF THE DISCLOSED INVENTION

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

Unless the context dictates the contrary, all ranges set forth herein should be interpreted as being inclusive of their endpoints, and open-ended ranges should be interpreted to include commercially practical values. Similarly, all lists of values should be considered as inclusive of intermediate values unless the context indicates the contrary.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

Lab tests were conducted to ascertain the problem of detecting a downed power line that could be easily revealed to the public. We used a 14.4 kV power transformer to simulate a high potential residential line that could provide power to a distribution transformer. One side of the line was grounded (using a rod) and the remaining terminal affixed to a cable in close proximity to the ground surface simulating a downed power line. When energized, the line in close proximity to the ground yielded significant arcing, producing a plasma that began to melt the local concrete. Ultraviolet and infrared light were emitted, and broadband RF interference was readily observed on our spectrum analyzer. Ultrasonic emissions from the arc could easily be detected hundreds of feet away, as could AM radio frequency emissions using a direction loop antenna connected to an oscilloscope or audibly using a simple diode/RC circuit for demodulation of the high frequency envelope.

When we lifted one leg of the transformer above the ground supported on an insulating box, there was no arcing, but there was still a low-level acoustical emission due to corona discharges. Some current flow was apparent upon activation of the transformer primary and was accompanied by physical movement of the cables resulting from the induced B field. Acoustical emissions were observed in the ultrasonic range, and some infrared signature could be detected over time. The infrared would no doubt be magnified with a true transmission line carrying hundreds of amperes, while our setup was limited to a maximum of less than 250 milliamps. Radio frequency emissions were always accompanied by the acoustical detection of any corona, as is to be expected.

An ultrasonic downed power line detector was constructed using a Panasonic ultrasonic transducer with a center resonant frequency of 40 KHz. This transducer was buffered by two LM318 op amps in series and coupled to an RMS-DC converter to demodulate the signal into the audible spectra. An RMS-DC converter performs the same envelope detection that a rectifier and RC network achieves in a typical AM radio's detector stage. We also detected radio frequency emissions from both our simulated downed power line using a simple loop antenna and standard AM radio envelope detection. Arcing generates broadband radio noise from one kilohertz to over 1000 Megahertz. Above 50 Mhz, the magnitude of arcing RFI drops off.

Power lines can produce significant RF emissions in the event of a downed cable. The emission sources are almost always due to a line fault, spike, arc, or coronal formation. Because of some of the emissions possible in a transmission line, a telemetry function back to the utility that uses the transmission line itself as carrier was rejected in lieu of a spread spectrum approach—not to mention the fact that a downed wire could be physically disconnected from the source and be incapable of sending information. Some other sources of radio interference from power lines include: [0028] Incidental emitters: Most interference complaints from power-company equipment results from an incidental emitter. Incidental emitters don't intentionally generate radio energy, but incidentally does so as a result of its operation. Examples of incidental emitters include electric motors and sparking power-line hardware. Unintentional emitters: These may be found in some power-company equipment. Unintentional emitters utilize an internal radio signal, but do not intentionally radiate or transmit it. Examples include some types of “switch-mode” power supplies and microprocessors used in some power-company equipment. Unintentional emitters have specific limits on radiated and conducted emissions. Intentional emitters: These are transmitters that intentionally radiate RF. In general, they are not found in power company equipment, although some remote-reading usage meters may use intentional emitters.

In one embodiment of the disclosed invention, radio frequency detection may be combined with ultrasonic acoustical emission detection. Ultrasonic emissions are highly directional and can be used to help pinpoint possible points of high voltage arcing due to a failed power line.

After consideration of the various options for the disclosed transmission line status indicator invention, we had to envision how it would be best to deploy such devices. We knew we could detect a power line arc or corona acoustically, visually, thermally, and wirelessly from RF emissions from a distance; however, not all downed lines may be arcing. If the voltage is low, but current high, such as would be the case for a 120-volt leg from a distribution transformer, there could still be a significant hazard present.

The objective for an ideal line sensor would be to identify a downed line regardless of the voltage, current, energy emissions, or noise on the line. In any power transmission line, as thousands of utility customers add/remove loads onto a transmission line, significant noise can be present from inductive, capacitive, and even transitory short circuit loads. Transmitting a signal from a line detector through the grid across possibly multiple transformers amongst background noise to a command center can be challenging. A utility may wish to limit the spectral bandwidth on their transmission lines to avoid spurious emission or interfering with internal equipment data exchange. The question to be answered remains, how best to detect a line anomaly and report a suspected downed wire condition back to a central station, while protecting the public?

One aspect of the disclosed invention is the use of a smart phone in conjunction with a smart line sensor. Addressing each component of the invention, we will consider the latter first. The first aspect of the invention is an inductively coupled line sensor that can ‘clamshell’ around standard power lines. The inductive sensor would contain a transformer/coil to inductively provide device power, which is rectified and filtered to a low voltage DC supply. Relevant precedents include inductive ‘clamp’ ammeters and some remote cameras and other monitors. When a power line is undamaged and connected in a circuit with a load, there is of course an associated magnetic field. If the load disappears, the magnetic field strength also disappears, as there is no longer any current flow. However, the mere presence of a conductor in close proximity to an active line will still detect a 60 Hz signal. Thus, the disclosed invention includes a circuit that can be triggered by the loss of a B field but yet still detects a 60-Hz electric field, we know the line is still a danger to the public. The loss of both the magnetic and electric field reveals a dead line. The preferred embodiment contains a battery backup, solar cell for battery charging, and a micro-controller that is configured to log transient line information, the date and time when the line break occurred, and the means to display line condition audibly and visually. Transmission of line status back to a central office is preferably effected using low power spread-spectrum technology. Use of spread spectrum allows for low power consumption commensurate with FCC rules yet relatively long distance communication between line status indicators. An added embodiment of the disclosed invention line monitors is that multiple units can serve as ‘nodes’, which pick up and shuttle line indicator status information in a ‘bucket-brigade’ fashion, each line detector serving as part of a larger telemetry chain. The benefit of this approach is that such a system is immune to line noise, line transformers in the network, and does not rely on the presence of local cellular towers as repeaters.

In the preferred embodiment, visual indication is ideally provided using high intensity, low powered LEDs. The LEDs can be Red, Yellow, or Green depending on the level of potential hazard, mimicking of course an ordinary traffic light. Another embodiment is an aural warning that can be achieved using low powered piezo-electric transducers such as the chirps found in smoke detector low battery warnings. The line monitor chip duty cycle can be set to prolong sensor battery life for days or weeks yet provide long-range warning. The combination of flashing visual and pulsing audible alarms even in the absence of line connection would serve to protect bystanders and yet assist line crews on the condition of a specific line in question.

The next aspect of the disclosed invention for a line monitor system includes the use of a smart phone. The iPhone has a magnetometer, a magneto-resistive permalloy sensor, the AN-203 chip produced by Honeywell. When we approached our 14.4 kV simulated downed line; we were able to detect a significant change in magnetometer readings. As such, one embodiment of the disclosed invention is a smart phone app or software application that could employ a fusion of sensory inputs from a smart phone to detect a live power line. Such a fusion of technologies may use an external phone interface that contains an ultrasonic transducer (the frequency range of the iPhone microphone is unsuited for this) and a PC board directional RF antenna. Such antennas are now routinely employed on circuit boards using fractal analysis.

But what if we want to use a smart phone without any external attachments?

One embodiment of the disclosed invention would be a fusion of phone app and the stand-alone line sensor. The visual indicator for our line sensor was already described as being an LED. This type of visual device can be strobed to provide a remote data link from the power line to the smart phone camera. The benefit here is that we can use the same detection spectra of the built-in CCD sensor and extract data stream information transmitted by the line monitor regarding the line ID number, voltage, date and time of interruption, and much more. And because the data rate will be faster than the human eye can sense, the LED will appear to be illuminated continuously. A cell phone so equipped with such an app can also use the cellular network to rely this line information to a central office. Indeed, the app can even provide GPS information to line crews as to the proximity of known lines with trouble. The beauty of this dual approach, stand-alone line monitor and smartphone inter-connectivity capability, is that neither is dependent on the other. The stand alone line sensor can function without the phone, and the phone can provide data about the line. An app can also be downloaded in a matter of seconds to any first responder and can be upgraded dynamically as new data emerges about the potential area line threats. To test part of this concept, we created a simple magnetometer app, which did reveal our simulated line hazard!

iPhone Camera Telemetry Capability—IR LED Detection Example

If one has an iPhone, the fact that the built-in CCD camera can detect partly in the IR spectrum for remote LED monitoring can easily be demonstrated. The ability of a smart phone to detect infrared emissions can be tested as follows; using an iPhone, start the Camera app, and point the camera at the LED toward a TV remote control. As you look at the iPhone screen, press any button on the remote. Although the remote is transmitting a bright infrared light beam, one cannot see it with your eye because obviously your eye is not sensitive to light in the frequency of infrared (around 940 nm for a remote control). The iPhone's main camera cannot detect infrared light, because Apple added a filter over the lens that blocks out infrared light, so the infrared light cannot be seen on the screen. Now press the “switch cameras” icon in the upper right corner of the iPhone's Camera app so that the FaceTime camera's view is being displayed on the screen. You will see yourself on the screen. Now point the FaceTime camera at the LED end of your TV remote control and press a button on the remote. Your eye can't see the IR light, but now you will see the IR light appear in the viewfinder as a bright white light. It turns out that the FaceTime camera on an iPhone does NOT have IR filtering on it!

Detail of Proposed Stand-Alone Line Monitoring Nodes

In yet another embodiment of the disclosed invention, for a typical 3-phase transmission line, a single transmission line monitor is clamped onto each of the three (or more) lines. The “trio” of monitors would need to be placed throughout the transmission line grid at intervals of short distance for congested, urban areas, of about one trio every half mile. For more rural areas, a longer interval could be used, of one trio every one or two miles. Because the proposed transmission line monitors are capable of being “clamped” onto a live transmission line, there is no need to have a hard wire connection to the transmission line. The desirability of this is that a single lineman can quickly and effectively connect many of these devices in a single shift.

The device is constructed to include two clamping clips that lock the transmission monitor around the transmission line. A lineman can thus clamp one of the transmission line monitors in literally seconds. Once clamped on, the transmission line monitor will immediately start charging the internal rechargeable battery, and will indicate its operational status on the unit's LED's (light emitting diodes).

With the advances in LED technology available today, a single led can be highly visible from many yards away, even in daylight. Aside from providing a simple visual indication of the transmission line monitors status, the LED's can provide communication to a remote optical detector, such as a cell phone. The encoded data will provide information such as how long the “event” has been active, what the “event” was that occurred, and whether there is any current flowing through the transmission line. The LED can also optically encode whether there is any voltage present on the transmission line.

The transmission line monitor contains a rechargeable battery that will provide internal power in the case of a downed line. The theory behind the operation of the transmission monitor as innovative, but well grounded in theory. When current is flowing through a transmission line, a coil of wire wrapped around the transmission line will produce an electrical current. This induced current powers the transmission line monitor. Because the circuitry is highly efficient and low power, very little current is required to power it. The required current is estimated at approximately 5 milliamps in standby, 30-50 mA in active alert mode. The wire coil-core is similar to the clampable cylindrical opening, such as what is used by many AC wireless current sensors.

In one version of the proposed device, when the transmission monitors are monitoring a current flow and detecting an electric field, they will indicate a “Normal” status by illuminating the green LED. If there is a problem with the transmission line monitor or an intermittent abnormal condition on the transmission line, the yellow LED will illuminate. The microcontroller and LED drive circuit is also capable of encoding information optically, which can be interpreted by a cell phone running an appropriate App. A red LED will illuminate when there is a sudden loss of the B (magnetic) field (no current/load) along with a time matched physical drop in the transmission line as detected by a MEMS accelerometer chip (Analog Devices, Norwood, Mass.), There may also be a loss of the electric field. A situation can arise where there is a break in one of the three transmission lines, where the load side is without power, while the source side is still live or “hot”, but no current (or minimal current) is flowing through the transmission line. In this case, the transmission line monitor that is on the source side will indicate a red LED, with encoded optical data reporting loss of current, but still showing a live or “hot” transmission line. An audible alarm will be sounded under this condition. The activation of the audible alarm can be over-ridden by the utility via RF telemetry or optical communication with the line monitor. By rapidly comparing transmission line monitors that are spaced some distance apart, an indication can be given as to the approximate location of the break or downed line. Due to the minimal power required to operate the transmission line monitor, the transmission monitor can be constructed as a small footprint device, preferably 4 to 6 inches long, by 3 inches wide by 4 inches high, depending on the level of functionality desired.

It has long been established that LED's are highly efficient sources of illumination, but what is not as widely known is that the same LED can be used in a reciprocal manner, they can also sense light! Forrest M. Mims III made the discovery of this “dual use” of LED's as light sensors over a decade ago. Forrest wrote a paper for Applied Optics magazine in 1992, entitled “Sun Photometer with Light-Emitting Diodes as Spectrally Selective Detectors”. In this paper Forrest describes how to use LED's in a reciprocal role as a narrow band light sensor. The LED functions as a narrow band, wavelength specific light detector. In traditional Sun photometers, a light detector such as a wide optical bandwidth Photo-Diode is used in conjunction with a narrow band optical filter to determine the intensity of a specific wavelength of light. In fact Forrest M. Mims III was contracted by Radio Shack to develop a small portable multi-wavelength “Sun & Sky Monitoring Station”. The “Sun & Sky Monitoring Station” allows the user to collect very professional data related to Solar and Atmospheric conditions. In the preferred embodiment of the disclosed invention, the indicator LED's are being used in a dual role as a source of illumination and as a wavelength specific detector. Since the LED cannot do both things at the exact same time, the microcontroller must periodically place the indicating LED in a reversed bias condition. This can be achieved by utilizing a relay to change the polarity of the LED and connect it to the input of an operational amplifier (op-amp) circuit. Most microcontrollers have basic I/O (Input/Output) connections that can be configured as an input sensing pin or an output pin. When configured as an output pin, the pin can be placed in a high state (+5 volts or +3.3 volts in the case of lower voltage microcontrollers) or a low state (0 volts). When the microcontroller I/O pin is configured as an input, there is usually an internal pull up resistor that is switched in by the microcontroller. If the microcontroller's I/O pin senses a +5V level, it will read this as a logic one or high logic state. If the microcontroller's I/O pin senses a 0 V level, it will read this as a logic zero or low logic state. When the microcontroller is placed in the “listen” state, it will place one of the specific color LED's in a reversed bias state, while also connecting the LED to the output of an op-amp. The output of the op-amp will need to be connected to a comparator as the intensity of the incident light on the reversed bias LED will not be equal to +5 volts (maximum incident light) or 0 volts (minimum or no incident light. The comparator will have a low threshold voltage in which any time this threshold is exceeded, the comparator will output a logic high or +5 volts. This will be read in by the microcontroller, and the duration of the time the pin is at logic high will correspond to a “bit” or portion of a serial command. The microcontroller will have a pre-programmed set of specific commands that it will expect to read from an external source, such as a utility worker with a smartphone and a proprietary App. To facilitate this communication, most microcontrollers contain a special device called a UART (Universal Asynchronous Receiver Transmitter).

Asynchronous transmission allows data to be transmitted without the sender having to send a clock signal to the receiver. Instead, the sender and receiver must agree on timing parameters in advance and special bits are added to each word which are used to synchronize the sending and receiving units.

When a word is given to the UART for Asynchronous transmissions, a bit called the “Start Bit” is added to the beginning of each word that is to be transmitted. The Start Bit is used to alert the receiver that a word of data is about to be sent, and to force the clock in the receiver into synchronization with the clock in the transmitter. After the Start Bit, the individual bits of the word of data are sent, with the Least Significant Bit (LSB) being sent first. Each bit in the transmission is transmitted for exactly the same amount of time as all of the other bits, and the receiver “looks” at the wire at approximately halfway through the period assigned to each bit to determine if the bit is a 1 or a 0. For example, if it takes two seconds to send each bit, the receiver will examine the signal to determine if it is a 1 or a 0 after one second has passed, then it will wait two seconds and then examine the value of the next bit, and so on.

The sender does not know when the receiver has “looked” at the value of the bit. The sender only knows when the clock says to begin transmitting the next bit of the word. When the entire data word has been sent, the transmitter may add a Parity Bit that the transmitter generates. The Parity Bit may be used by the receiver to perform simple error checking. Then at least one Stop Bit is sent by the transmitter.

When the receiver has received all of the bits in the data word, it may check for the Parity Bits (both sender and receiver must agree on whether a Parity Bit is to be used), and then the receiver looks for a Stop Bit. If the Stop Bit does not appear when it is supposed to, the UART considers the entire word to be garbled and will report a Framing Error to the host processor when the data word is read. The usual cause of a Framing Error is that the sender and receiver clocks were not running at the same speed, or that the signal was interrupted.

Regardless of whether the data was received correctly or not, the UART automatically discards the Start, Parity and Stop bits. If the sender and receiver are configured identically, these bits are not passed to the host.

If another word is ready for transmission, the Start Bit for the new word can be sent as soon as the Stop Bit for the previous word has been sent.

Because asynchronous data is “self synchronizing”, if there is no data to transmit, the transmission line can be idle.

Both the microcontroller and the external communication device must know ahead of time what the correct communication parameters are for this to work. Typical parameters when programming a UART are the number of bits in a word, the number of stop bits used, the parity of the word, and the BAUD rate.

Baud rate is a measurement of transmission speed in asynchronous communication. In the preferred embodiment of the disclosed invention, the BAUD rate will not be that high, typically 9600 BAUD. With a higher BAUD rate, there is a greater chance for error due to any movement from either the handheld smartphone, the power line sensor, or both. If the BAUD rate is too low, like 300 BAUD, then the operator will need to remain at the scene longer due to the increased amount of time required to send and receive data.

Typical data sent to the power line monitor will be a general query, asking the device to report its status to the remote smartphone. The status will indicate if the power line monitor is operating normally, or if there is a loss of a B field or E field, what direction the current is flowing in, if there has been any violent spatial changes indicative of a break or high winds, and determination as to the power line rechargeable batteries status.

Some consumer appliance manufacturers have developed appliances that have the ability to be remotely controlled by a utility company, such as switching an air conditioner to a low power mode during times of peak power demand in the summer. Based on the fact that more and more digital or analog information may be superimposed onto transmission lines, it is advisable to have a system that does not add to the amount of possible line “chatter”. With the use of optically encoded data, a transmission monitor could communicate significant amounts of data to a cell phone equipped with a suitable App while remaining at a safe distance. An optical sensor could provide for two-way communication with the transmission line monitor while allowing the user to remain a safe distance away from the transmission line. An alternative would be using the Bluetooth capability of many smart phones. An evaluation of optical or Bluetooth line interrogation of the line monitor will be part of the proposed Phase I study. Consideration will also be given to the use of a GPS module. Such modules produced by Texas Instruments and Linx Technologies can provide a spatial displacement capability to the power line monitor. If a line breaks, the change in sensor orientation can be detected and transmitted to the utility. Another benefit would be displacement data in high winds for transmission towers.

Power Line Monitor Components

These stand-alone units will be designed to easily clamp around a power line, and will derive power inductively. The units will have battery backup, and contain a microcontroller along with analog detection circuitry to determine the presence/loss of a load and an electric field. The status, date and time, will be able to be transmitted using a spread spectrum module to a PC. In addition, loss of load/connection will be accompanied by visual LED indication and a piezo audible alarm. The serial data pulse train will also be part of the LED cycle.

### REFERENCE NUMERALS IN DRAWINGS

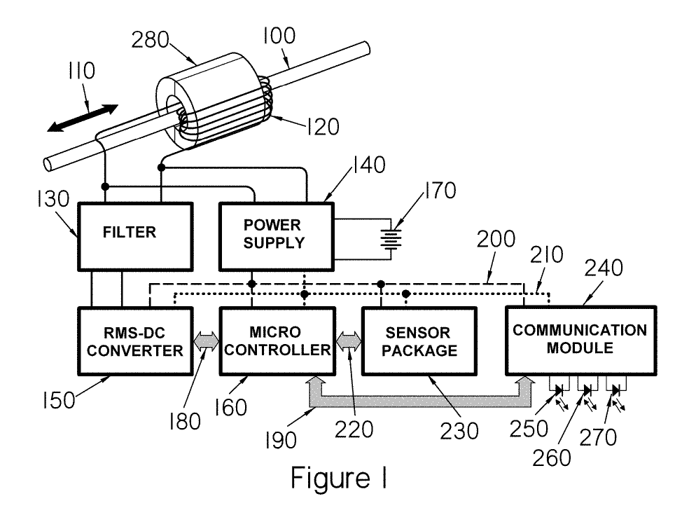

FIG. 1:
100 Denotes a small section of a functioning transmission line.
110 Denotes an arrow that represents that an AC current is flowing to a load through the transmission line.
120 Denotes a loop of wire that makes up the secondary of a transformer.
130 Denotes a block diagram representing a filter to smooth out the voltages pulses from the secondary of the transformer.
140 Denotes a block diagram representing the power supply section of the circuit.
150 Denotes a block diagram representing an RMS converter that will be used to determine a value of current running through the transmission line.
160 Denotes a block diagram representing the microcontroller that will perform all the logic and control functions of the disclosed invention.
170 Denotes a schematic representation of a rechargeable battery that will provide backup power to the disclosed invention in the event of loss of current through the transmission line.
180 Denotes a bi-directional bus that can send and receive information between the microcontroller and the RMS converter.
190 Denotes a bi-directional bus that can send and receive information between the microcontroller and the Communication Module.
200 Denotes a schematic representation of one side of a power connection that will supply power to each of the individual sections of the circuit.
210 Denotes a schematic representation of one side of a power connection that will supply power to each of the individual sections of the circuit.
220 Denotes a bi-directional bus that can send and receive information between the microcontroller and the Sensor Package.
230 Denotes a block diagram representing the Sensor Package that contains all the individual sensors used to analyze ambient conditions.
240 Denotes a block diagram representing the Communication Module that contains all the communication circuitry that will be used to communicate device status and line conditions to a remote user.
250 Denotes a schematic symbol for an LED that will be used to communicate device status and line conditions to a remote user.
260 Denotes a schematic symbol for an LED that will be used to communicate device status and line conditions to a remote user.
270 Denotes a schematic symbol for an LED that will be used to communicate device status and line conditions to a remote user.

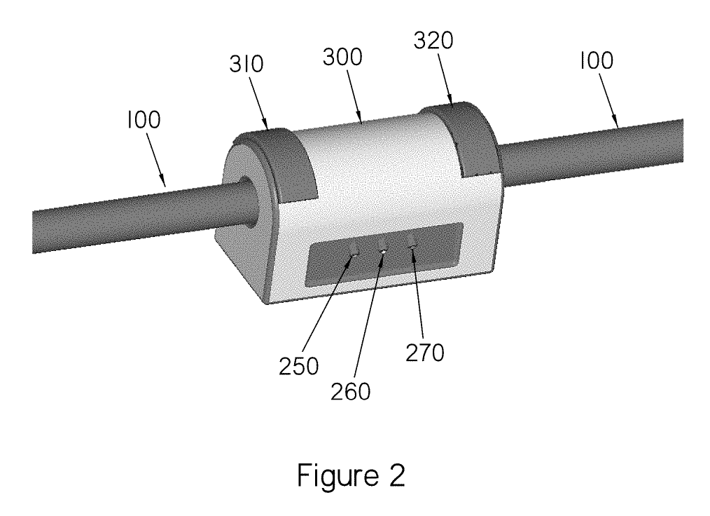

FIG. 2:
100 Denotes a small section of a functioning transmission line.
250 Denotes a schematic symbol for an LED that will be used to communicate device status and line conditions to a remote user.
260 Denotes a schematic symbol for an LED that will be used to communicate device status and line conditions to a remote user.
270 Denotes a schematic symbol for an LED that will be used to communicate device status and line conditions to a remote user.
300 Denotes the weatherproof, insulating housing in a closed position attached to a power line containing all the described circuitry.
310 Denotes a latch that is used to hold the weatherproof, insulating housing in a closed position while it is attached to a power line.
320 Denotes a latch that is used to hold the weatherproof, insulating housing in a closed position while it is attached to a power line.

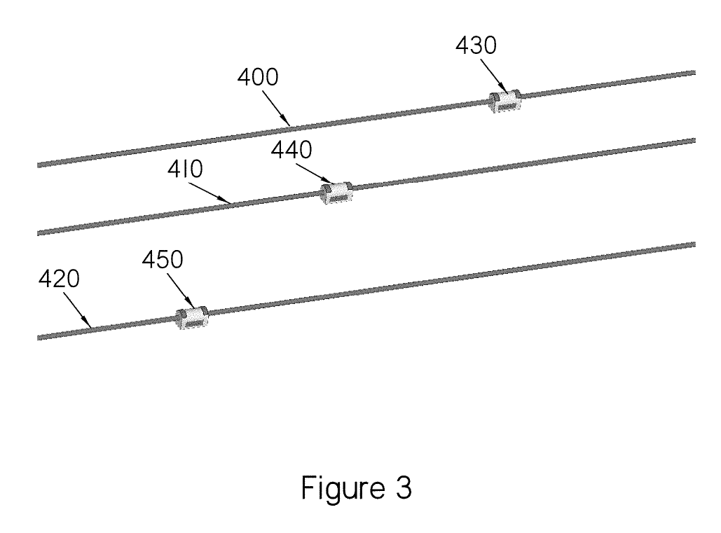

FIG. 3:
400 Denotes a small section of one line of a functioning three-phase transmission line.
410 Denotes a small section of one line of a functioning three-phase transmission line.
420 Denotes a small section of one line of a functioning three-phase transmission line.
430 Denotes the weatherproof, insulating housing in a closed position attached to a power line containing all the described circuitry.
440 Denotes the weatherproof, insulating housing in a closed position attached to a power line containing all the described circuitry.
450 Denotes the weatherproof, insulating housing in a closed position attached to a power line containing all the described circuitry.

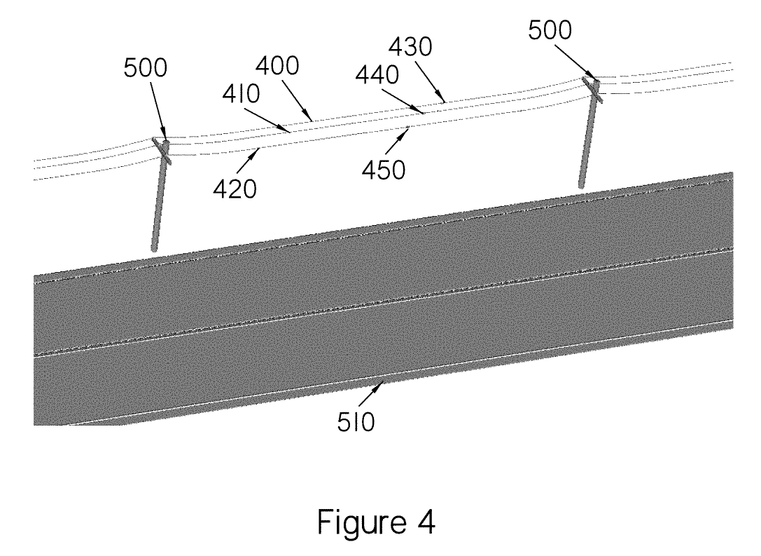

FIG. 4:
400 Denotes a small section of one line of a functioning three-phase transmission line.
410 Denotes a small section of one line of a functioning three-phase transmission line.
420 Denotes a small section of one line of a functioning three-phase transmission line.
430 Denotes the weatherproof, insulating housing in a closed position attached to a power line containing all the described circuitry.
440 Denotes the weatherproof, insulating housing in a closed position attached to a power line containing all the described circuitry.
450 Denotes the weatherproof, insulating housing in a closed position attached to a power line containing all the described circuitry.
500 Denotes a typical power line (telephone) pole as someone would see on the side of a roadway.
510 Denotes a typical asphalt roadway.

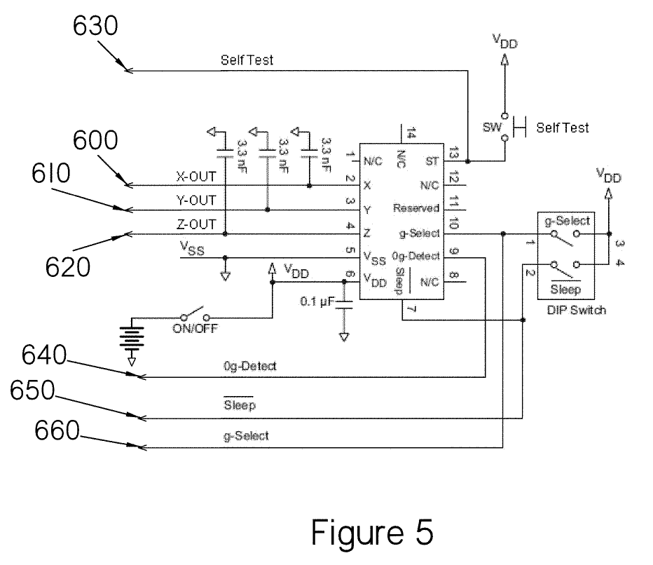

FIG. 5:
600 Denotes a wire connected to the “X-axis” output of three-axis accelerometer circuit.
610 Denotes a wire connected to the “Y-axis” output of three-axis accelerometer circuit.
620 Denotes a wire connected to the “Z-axis” output of three-axis accelerometer circuit.
630 Denotes a wire connected to the “Self Test” line of three-axis accelerometer circuit.
640 Denotes a wire connected to the “Zero G Detect” line of three-axis accelerometer circuit.
650 Denotes a wire connected to the “Sleep” line of three-axis accelerometer circuit.
660 Denotes a wire connected to the “G Select” line of three axis accelerometer circuit.

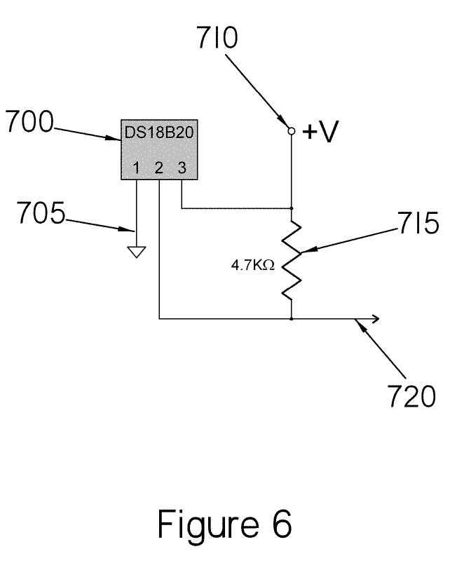

FIG. 6:
700 Denotes a schematic representation of a digital three terminal temperature sensor.
705 Denotes a schematic representation of a ground connection to the digital three terminal temperature sensor.
710 Denotes a schematic representation of a power connection to the digital three terminal temperature sensor.
715 Denotes a schematic representation of a resistor used to pull up the one wire communication line to the digital three terminal temperature sensor.
720 Denotes a schematic representation of the one wire communication line to the digital three terminal temperature sensor.

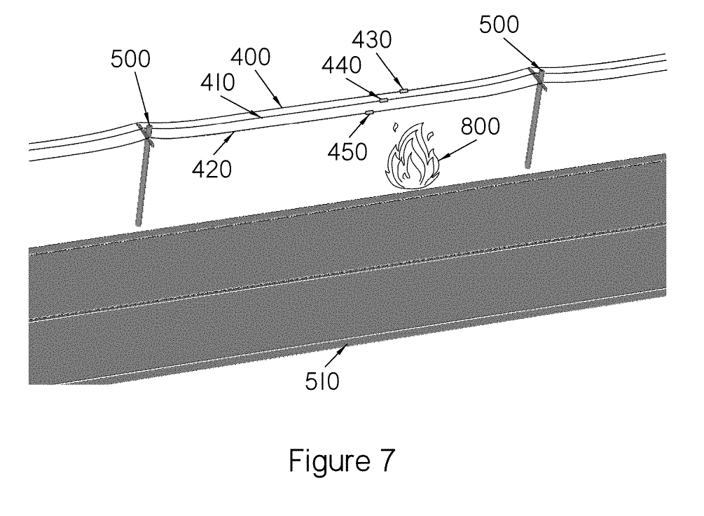

FIG. 7:
400 Denotes a small section of one line of a functioning three-phase transmission line.
410 Denotes a small section of one line of a functioning three-phase transmission line.
420 Denotes a small section of one line of a functioning three-phase transmission line.
430 Denotes the weatherproof, insulating housing in a closed position attached to a power line containing all the described circuitry.
440 Denotes the weatherproof, insulating housing in a closed position attached to a power line containing all the described circuitry.
450 Denotes the weatherproof, insulating housing in a closed position attached to a power line containing all the described circuitry.
500 Denotes a typical power line (telephone) pole as someone would see on the side of a roadway.
510 Denotes a typical asphalt roadway.
800 Denotes a representation of a brushfire next to a typical asphalt road way under the power lines.

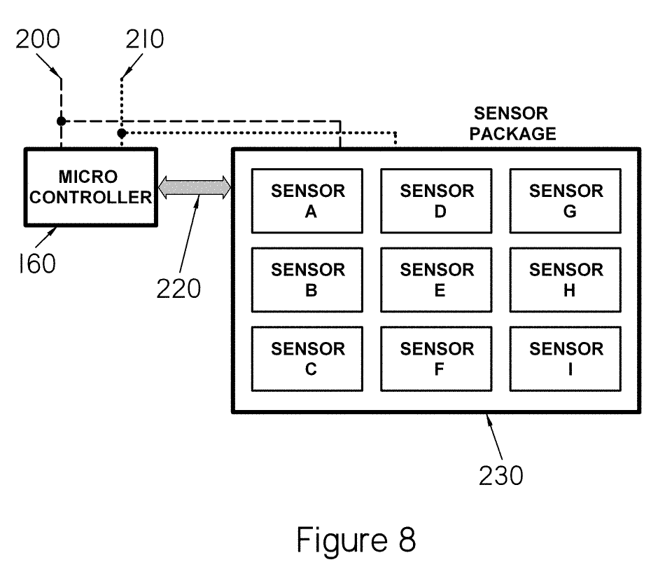

FIG. 8:
160 Denotes a block diagram representing the microcontroller that will perform all the logic and control functions of the disclosed invention.
200 Denotes a schematic representation of one side of a power connection that will supply power to each of the individual sections of the circuit.
210 Denotes a schematic representation of one side of a power connection that will supply power to each of the individual sections of the circuit.
220 Denotes a bi-directional bus that can send and receive information between the microcontroller and the Sensor Package.
230 Denotes a block diagram representing the Sensor Package that contains all the individual sensors used to analyze ambient conditions.

### THE DISCLOSED INVENTION OPERATION IN SUMMATION

Referring to the block diagram in FIG. 1 of the preferred embodiment system, which includes a split ferrite core 280 that can be enclosed like a clamshell around a transmission line 100 through which there is an alternating current 110 flowing. Inductive coil windings 120 derive both an alternating voltage signal which is filtered 130 preferably using a series resistor and a capacitor across the line. The output of the inductive coil 120 is also connected to a power supply module 140 which preferably contains a half wave or full wave diode rectifier followed by a series resistor and shunt capacitance sufficient to provide a direct current to rechargeable battery 170. The filtered electrical signal from 130 is connected to an RMS to DC converter such as an Analog Devices (Norwood, Mass.) AD536 or AD637 device. The signal from the RMS-DC Converter 150 is fed 180 into a microcontroller 160 which is programmed to look for several electrical state conditions as determined by a connection 220 to sensor package 230. The sensor package 230, RMS Converter 150, Microcontroller 160, and communication module 240 all derive operating power from connection 200 connected to the power supply 140. The sensor package 230 includes input options such as electrical field detection and angular, shock, or motion detection. In one embodiment, an accelerometer MEMS device such as the Analog Devices ADXL345, a three axis device, is capacitively coupled to a comparator circuit, such that any sudden change in spatial attitude in any axis will produce a transient alternating current signal that can be expressed through the capacitive coupling and into a comparator circuit and sampled against a predetermined reference voltage. A signal that exceeds the preset reference will be determined to indicate a sudden change in spatial orientation of a power transmission line as associated with a line break and subsequent drop of the line toward the ground. The microcontroller 160 is preferably programmed to detect the following state conditions; 1. presence of a B and E field, and no spatial change in sensor position; 2. loss of B field and presence of E field, no spatial change 3. loss of B and E field, sudden spatial change 4. loss of B field and presence of E field, sudden spatial change 5. transient loss or presence of B & E fields, spatial change, intermittent spikes 6. presence of B and E field, sudden spatial change.

Transient loss or presence of B & E fields, spatial change, intermittent spikes produce a signal 190 from the microcontroller 160 to be delivered to the communication module 240. The communication module contains internal logic, which activates visual LED status lamps such as preferably safe or green 250, potential hazard or yellow 260, and danger or red 270. Additional LED lamps may be added such as infrared emitting devices that can be strobed in a serial manner obvious to those skilled in the art to provide power line module status condition data derived from the microcontroller 160 and ground infrared receivers. The communication module in a preferred embodiment includes an acoustic alarm, such as a piezo buzzer to warn pedestrians of a power line hazard. In addition, in the preferred embodiment, the communications module is configured to provide RF communication with the power utility, cellular devices such as a smart phone, and simplex or duplex communication with other power line monitors. The microcontroller is connected to the RMS converter 150, sensor package 230, and communication module 240 by a data bus 190 and 220.

Effective Power Line Monitor Invention Key Innovations

First and foremost, the disclosed invention provides for a power line detector that can be easily affixed to any power line; derives operating power from the line; captures B field and E field data; and provide visual and/or audible alerts when the line is interrupted and/or arcs or produces a corona indicative of a downed wire. Telemetry capability in the form of a spread spectrum transmission is provided. Next, is the inclusion of a Smartphone application program that can detect magnetic field anomalies, and which can interface with the power line detector using Bluetooth, optical or other means to capture line status data.

The objectives solved by the disclosed invention include the development of a low cost, light weight, self-energized power utility cable monitor that is capable of alerting personnel in the immediate area and at a central utility facility about a line break. Another embodiment of the disclosed invention is to include a voice alert warning pedestrians to “Stay Away” from a downed line. Broken yet active power lines present an immediate threat to nearby individuals, and the lack of information concerning line failure during a storm or other event that results in a downed line can delay system repair. In addition, first responders can be compromised in rescuing individuals near a downed line for fear the line may present a shock hazard. The disclosed invention is designed to address the problem at hand, is a transmission line sensor assembly that can be quickly clamped around the power line. The device will contain the equivalent of a ‘clamp-on’ ammeter with a non-ferrous core to mitigate I.sup.2R losses. This ammeter circuit detects the presence of a load as a consequence of current flow, and analyzes line transients that may occur due to arcing or corona discharges. An additional coil located adjacent to the line serves as an air gap transformer to record the electric field. The unit derives operational energy from the line itself inductively. Signals from both B field and E field coils will be amplified and applied to an RMS-DC converter. The base line output of the converter will be compared to a user adjustable reference and using a comparator circuit, toggle a visual (LED) and aural (piezo buzzer) alert in the event of a line failure. A line failure may be determined using a fusion of sensor data to the comparator circuit. Using an accelerometer chip, such as the Analog Devices 3-Axis ADXL MEMS devices, the sudden release and drop of a power line can be determined. The presence of an electric field even in the absence of corona or arcing would signify an alert condition. Reporting of line status will be accomplished using spread spectrum technology derived from off-the-shelf transponder modules. Each line monitor will have the capability of receiving and forwarding a line monitor alert bucket-brigade style to a central office or from a cell phone equipped with cell phone software. Spread spectrum was chosen because transmission of data packets on the transmission line itself may be difficult due to line noise associated with downed cables (corona/arcing) and reactive attenuation of RF signals through transformers. A flashing red warning LED can appear to the eye constant, but actually be cycled with a data bit stream received by a Smart phone. The transmission line can detect for the presence of an improperly connected electrical generator during a power failure. If someone connects a home generator to a fuse box and forgets to disconnect the main breaker, power can be back fed into the lines that can injure or kill a lineman.

Because transmission lines are extremely noisy (before distribution transformers) we need to obtain a uniform value of the B and E fields. To accomplish this, in the preferred embodiment employs averaging the signal using an RMS-DC converter (Analog Devices).

xxxx

### Glossary of Terms

B—Field: A magnetic field

E—Field: An electric field

LED: Light Emitting Diode

Diamagnetic: A material that has a weak, negative susceptibility to magnetic fields. Diamagnetic materials are slightly repelled by a magnetic field and the material does not retain the magnetic properties when the external field is removed. In diamagnetic materials all the electrons are paired so there is no permanent net magnetic moment per atom. Diamagnetic properties arise from the realignment of the electron paths under the influence of an external magnetic field. Most elements in the periodic table, including copper, silver, and gold, are diamagnetic.

Paramagnetic: A material that has a small, positive susceptibility to magnetic fields. These materials are slightly attracted by a magnetic field and the material does not retain the magnetic properties when the external field is removed. Paramagnetic properties are due to the presence of some unpaired electrons, and from the realignment of the electron paths caused by the external magnetic field. Paramagnetic materials include magnesium, molybdenum, lithium, and tantalum.

RF: Radio Frequency energy

Spatial Change: A deviation in physical orientation in space with respect to a predetermined initial condition. For the purposes of this disclosure, the output of an accelerometer or tilt sensor is nulled or cancelled out when a transmission line sensor clamped to a power transmission line is in a preferably horizontal position. A sudden break in a transmission line would subject the line sensor to traverse through physical space, typically an arc, resulting in the production of an electrical signal that corresponds to the rate and/or angle and/or g-force experienced by the sensor package. The spatial sensor is used to determine if a line break or severing has transpired, due to a sudden associated physical change in line monitor orientation as contrasted with a prior steady-state condition. A sudden transient in physical orientation in space of the sensor package for the line monitor assembly invention will result in a signal being produced at one or all of the X, Y, or Z accelerometer outputs 600, 610, and 620 in FIG. 5. The axis outputs 600, 610, and 620 in FIG. 5 are preferably coupled capacitively into a comparator circuit, which triggers a state condition change registered by the monitor microcontroller depicted in FIG. 1 as 150. Control functions in the preferred embodiment of the spatial orientation accelerometer sensor include a power-up self test 630, a 0-g reference 640 for establishing an initial condition, a power saving sleep state 650 control, and a g-level 660 sensitivity control.

### DETAILED DESCRIPTION OF DISCLOSED INVENTION

FIG. 1 is a block diagram of the preferred embodiment system, which includes a split ferrite core 280 that can be enclosed like a clamshell around a transmission line 100 through which an alternating current 110 is flowing. Inductive coil windings 120 derive both an alternating voltage signal which is filtered 130 preferably using a series resistor and a capacitor across the line. The output of the inductive coil 120 is also connected to a power supply module 140 which preferably contains a half wave or full wave diode rectifier followed by a series resistor and shunt capacitance sufficient to provide a direct current to rechargeable battery 170. The filtered electrical signal from 130 is connected to an RMS to DC converter such as an Analog Devices (Norwood, Mass.) AD536 or AD637 device. The signal from the RMS-DC Converter 150 is fed 180 into a microcontroller 160 which is programmed to look for several electrical state conditions is connected by a data bus 220 to sensor package 230. The sensor package 230, RMS Converter 150, Microcontroller 160, and communication module 240 all derive operating power from connection 200 and 210 connected to the power supply 140. The sensor package 230 includes input options such as electrical field detection and angular, shock, or motion detection. In one embodiment, an accelerometer MEMS device such as the Analog Devices ADXL345, a three axis device, is capacitively coupled to a comparator circuit, such that any sudden change in spatial attitude in any axis will produce a transient alternating current signal that can be expressed through the capacitive coupling and into a comparator circuit and sampled against a predetermined reference voltage. A signal that exceeds the preset reference will be determined to indicate a sudden change in spatial orientation of a power transmission line as associated with a line break and subsequent drop of the line toward the ground. The microcontroller 160 is preferably programmed to detect the following state conditions;
1. presence of a B and E field, and no spatial change in sensor position;
2. loss of B field and presence of E field, no spatial change
3. loss of B and E field, sudden spatial change
4. loss of B field and presence of E field, sudden spatial change
5. transient loss or presence of B & E fields, spatial change, intermittent spikes
6. presence of B and E field, sudden spatial change

Transient loss or presence of B & E fields, spatial change, intermittent spikes produce a signal 190 from the microcontroller 160 to be delivered to the communication module 240. The communication module contains internal logic, which activates visual LED status lamps such as preferably safe or green 250, potential hazard or yellow 260, and danger or red 270. Additional LED lamps may be added such as infrared emitting devices that can be strobed in a serial manner obvious to those skilled in the art to provide power line module status condition data derived from the microcontroller 160 and ground infrared receivers. The commination module in a preferred embodiment includes an acoustic alarm, such as a piezo buzzer to warn pedestrians of a power line hazard. In addition, in the preferred embodiment, the communications module is configured to provide RF communication with the power utility, cellular devices such as a smart phone, and simplex or duplex communication with other power line monitors. The microcontroller is connected to the RMS converter 150, sensor package 230, and communication module 240 by a data bus 180, 190, 220.

FIG. 2 is a preferred embodiment of the disclosed power transmission line monitor invention. A clamshell housing 300 encircles a power transmission line 100. The clamshell is held closed using retaining strips 310 and 320. Visual status LED lamps are located on the outside face of the monitor assembly and denoted by a green lamp 250, yellow lamp 260, and red lamp 270.

FIG. 3 is a perspective view of three parallel power line monitors 430, 440, and 450, each being equipped with a sensor used by the invention. Three phase power transmission lines are represented by 400, 410, and 420 respectively.

FIG. 4 is a preferred embodiment of the disclosed invention located next to a roadway 510, a typical location for power transmission lines 400, 410, and 420. The transmission lines are supported by poles 500. Line monitors 430, 440, and 450 are preferably staggered with respect to one another along the transmission line.

FIG. 5 is a preferred embodiment of the disclosed invention spatial attitude sensor, which is part of the sensor package in FIG. 1 identified as 230. The spatial sensor is used to determine if a line break or severing has transpired, due to a sudden associated physical change in line monitor orientation as contrasted with a prior steady-state condition. A sudden transient in physical orientation in space of the sensor package for the line monitor assembly invention will result in a signal being produced at one or all of the X, Y, or Z accelerometer outputs 600, 610, and 620. The axis outputs 600, 610, and 620 are preferably coupled capacitively into a comparator circuit, which triggers a state condition change registered by the monitor microcontroller depicted in FIG. 1 as 150. Control functions in the preferred embodiment of the spatial orientation accelerometer sensor include a power-up self test 630, a 0-g reference 640 for establishing an initial condition, a power saving sleep state 650 control, and a g-level 660 sensitivity control.

FIG. 6 details the thermal sensing circuit that is a preferred embodiment of the disclosed inventions thermal sensor, which is part of the sensor package in FIG. 1 identified as 230. Two thermal sensing circuits will be utilized, with one circuit used to measure temperature close to the transmission line and the other used to measure ambient temperature. The thermal sensing circuit consists of a digital thermometer 700 that provides Celsius temperature measurements over a 1-Wire bus 720. The digital thermometers communication line is 720 connected to one pin of the microcontroller and pulled up to the supplied power through a resistor 715 to positive voltage 710. The digital thermometer is also tied to system ground 705. The DS18B20 digital thermometer has the ability to convert the ambient temperature value to a digital conversion value of nine, ten, eleven, or twelve bits. The number of digital conversion bits corresponds to the temperature resolution. Nine conversion bits corresponds to a temperature resolution of increments of 0.5° C., while ten, eleven, and twelve correspond to temperature resolution increments of 0.25° C., 0.125° C., and 0.0625° C., respectively. In the preferred embodiment of the disclosed invention, the number of digital conversion bits will be set to nine conversion bits corresponding to a temperature resolution of increments of 0.5° C. The main reason for having a temperature sensor is to monitor for the presence of extreme heat, such as extreme heating of the transmission line as well as sensing a fire. It is more likely that the presence of a large ground fire will be sensed by the digital thermometer. The DS18B20 digital thermometer measures temperatures from −55° C. to +125° C. (−67° F. to +257° F.).

Due to the fact that most electronics will only function properly at a temperature of about half of the maximum, the microcontroller circuitry will need to be contained within thermal shielding. Additionally, the ambient temperature digital thermometer will be extended outside of any thermal shielding to allow sensing of ambient conditions. In addition to alerting the relevant individuals in charge of transmission line safety in case of fire, a low temperature alarm can also provide a pre-emptive notification. If the ambient temperature was at or below freezing, and the transmission line was also at or below freezing, and there was freezing rain forecast, it could indicate that the transmission line could ice up. During a transmission line icing condition, excess weight of the ice on the transmission line could cause possible line breakage or if the amount of transmission line droop holds it too close to the ground or a tree branch, an arc may occur. By closely monitoring the ambient temperature and the transmission line temperature, preventative maintenance can be augmented. If a transmission line is heating up while the ambient temperature is not, this could be indicative of an excessive amount of current through the transmission line. Since the transmission line sensor monitors the magnetic field, and in turn, the amount of current through the transmission line, the temperature measurement can indicate that a transmission line heating up, while the magnetic field, and hence, current, remain approximately consistent, the transmission line may have a flaw that could indicate an immanent failure. By transmitting this data to the relevant individuals in charge of transmission line safety could send some lineman to investigate the situation before the transmission line has a catastrophic failure.

FIG. 7 shows the preferred embodiment of the disclosed invention located next to a roadway 510, a typical location for power transmission lines 400, 410, and 420. The transmission lines are supported by poles 500. Transmission line monitors 430, 440, and 450 are preferably staggered with respect to one another along the transmission lines. In the extreme situation in which there is a brush or ground fire 800 within close proximity to the transmission line monitors 430, 440, and 450, each of the transmission line monitors will measure a sudden increase in ambient temperature. This sudden increase will be indicative of a brush or ground fire and the microcontroller, which is part of the sensor package in FIG. 1 identified as 230, will indicate an alarm condition through use of the communication module in FIG. 1 identified as 240 which includes multicolored LED visual indicators, an acoustic alarm, such as a piezo buzzer to warn pedestrians of a power line hazard, and is configured to provide RF communication with the power utility, cellular devices such as a smart phone, and simplex or duplex communication with other power line monitors. Due to the unique nature of LED's to switch on and off rapidly, a coded optical message could be sent to a capable optical receiver located within a short distance from the transmission line monitor. The LED can rapidly flash a specific pattern of pulses that can be read with an appropriate optical receiver that would be able to read the status of the transmission line monitor. The status information could be a repeated series of status codes indicating the conditions that were monitored, such as temperature, electric current, any excessive 3-axis shock, and the time and date of the occurrence. Because the LED's can be switched on and off so rapidly, it would be impossible for the human to interpret this information. As stated previously in this specification, Forrest M. Mims III has long pioneered the “dual use” of LED's as not only sources of illumination, but also as narrow band light sensors. Forrest wrote a paper for Applied Optics magazine in 1992, entitled “Sun Photometer with Light-Emitting Diodes as Spectrally Selective Detectors”. In this paper Forrest describes how to use LED's in a reciprocal role as a narrow band light sensor. Since the LED cannot do both things at the exact same time, the microcontroller must periodically place the indicating LED in a reversed bias condition. In this way, the individual LED's can serve as a duplex method of serial communication. Each individual transmission line monitor can be interrogated by a remote optical transceiver that can be either a truck mounted unit, a portable, hand held unit, or a small, lightweight unit capable of being carried by a small autonomous drone to provide long range monitoring of the transmission lines. In addition to measuring an ambient temperature increase near the transmission lines due to a fire, there may also exist a situation where the fire is locally heating a transmission line some distance away from the transmission line sensor where the ambient temperature has not changed much, but the transmission line itself may be heating up due to exposure to a fire or heat source. In this case, by transmitting this data to the relevant individuals in charge of transmission line safety, lineman could be sent to investigate the situation before the transmission line has a catastrophic failure. Any transmission line failure can cost thousands, if not hundreds of thousands of dollars in damage to infrastructure. In extreme situations, in which a transmission line failure causes a large wild fire, as has happened in the state of California over recent years, the damage could result in the loss of infrastructure, livestock, homes, and lives, and could potentially run into billions of dollars! By carefully and closely monitoring ambient conditions around transmission lines as well as the conditions of the transmission line itself, diagnostic information can be produced that will allow the relevant individuals in charge of transmission line safety to investigate a potential hazardous situation before the transmission line has a catastrophic failure.

FIG. 8 is a block diagram showing additional detail of a portion of what is contained in FIG. 1, specifically, the sensor package 230. The individual sensors utilize power derived from the current flowing through the attached transmission line through connections 200 and 210. A bus 220 serves as a communication bus containing all relevant signals to allow successful communication between the microcontroller 160 and each individual sensor.

The bus 220 could be a data bus and address bus as is commonly found in microcontroller circuits, or a single 1-wire communication line. In the preferred embodiment of the disclosed invention, the bus 220 is a single line connected to each of the communication pins of the individual sensors. Each individual sensor will have a unique address that allows the microcontroller to communicate individually to each sensor contained within the sensor package 230. The basis of 1-Wire technology is a serial protocol using a single data line plus ground reference for communication. A 1-Wire master initiates and controls the communication with one or more 1-Wire slave devices on the 1-Wire bus.

Each 1-Wire slave device has a unique, unalterable, factory-programmed, 64-bit ID (identification number), which serves as device address on the 1-Wire bus. By minimizing the number of connections required for each individual sensor, a smaller footprint can be realized. It should be obvious to those skilled in the art that several valid schemes are known for communicating with a microcontroller, and although the 1-Wire method is preferred, it is not the only valid method. The communications bus 220 can just as easily contain a four or eight bit data bus, with several address lines used for addressing each individual sensor. In the hopes of keeping manufacturing costs down, the 1-Wire communication method is the preferred embodiment. The sensor package 230 contains a plurality of possible sensors, labeled Sensor A through Sensor I. There are several different types of sensors that will be contained within the sensor package 230. An example of some necessary sensors would be a 3-axis accelerometer to measure shock on the line, such as to indicate if a tree branch or some large object were to strike the transmission line or if the transmission line were suddenly disconnected from its secure mounting. During times when a large storm or hurricane has occurred, the data from the 3-axis accelerometer could help people quickly go to sections of the transmission line that may have been damaged due to excessive vibration, sway or shock. It is obvious to those skilled in the art that there exists several microcontrollers that contain an integrated MEMs based 3-axis accelerometer. Other examples would be the previously described digital thermometer to measure ambient as well as the temperature of the actual transmission line itself. Smoke detection sensors could be added to transmission line monitors located in large grassy plains to help indicate the presence of distant fires, but are designed in such a way as to not produce false indications due to high pollen count days. Radiation sensors could be added to transmission line monitors that are located in close proximity to nuclear power plants to give early warnings to any potential release of radioactive material. In urban areas, the transmission line monitor could be equipped with an audio sensor to listen for specific sounds such as gunshots, and report this information to local authorities. An infrared sensor could be added to indicate the presence of individuals walking close to the transmission lines. This would be similar to the type of infrared sensor used to activate security lights that many people have installed in their homes that automatically turn on in the event of someone walking within the monitored area. The problem here would be that the infrared sensor would be activated if a person were within the monitored area or if a deer, bear, or other large animal walked into the monitored area. Another possible source of a false indication might be from a very small animal located very close to the infrared sensor, such as a bat or bird flying too close to the infrared sensor. To combat this, a camera could be added to the transmission line monitor to allow a remote operator to manually determine the source—human or animal—and make the appropriate call.

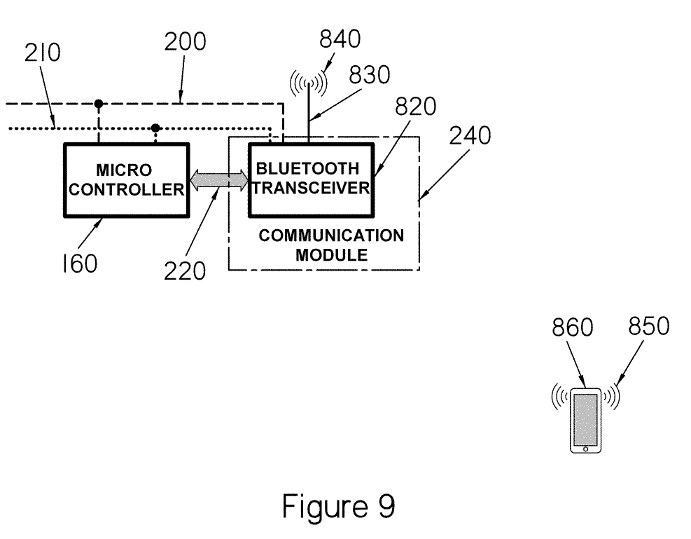

FIG. 9 is a block diagram detailing a segment of the communication module 240 illustrating the bluetooth communication module 820 that will allow a smart phone 860 with a proprietary app to remotely interrogate any power line monitor within range. The app will have the ability to detect specific bluetooth transmission sent from any power line monitor with range and record specific status information in the background, where the smart phone user does not have to perform any tasks to successfully transmit this status information to either the power line company or to a third party responsible for handling the power line monitors status data. As a smart phone 860 containing the proprietary app comes into range of any functioning power line monitor, it will detect transmitted bluetooth signals 840 sent from the bluetooth communication modules bluetooth antenna 830. When the smart phone 860 detects the transmitted bluetooth power line monitor signal, it will time stamp the event, along with storing the GPS coordinates of the power line monitor so the smart phone 860 can then transmit the power line monitors status condition, as well as the time, date, and GPS coordinates to the power company or to a third party company in charge of monitoring this data. In the case where the smart phone is in a “dead zone” where no cellular service is available, the smart phone app can temporarily store the data and transmit it when sufficient signal is available. In this way, any power line condition that indicates a possible hazard or mechanical problem could still be recorded and sent, but not in real time. In the preferred embodiment of the disclosed invention, the data would be sent in real time, or near real time to be most effective.

Due to the nature of bluetooth communication, the transmission range is limited to about thirty feet. Although smart phones 860 are described in the preferred embodiment of this disclosed invention, it is important to indicate that there are situations in which power lines are located in remote areas where few, if any, smart phones will be within range to acquire the power line monitors data. With the prevalence of small intelligent drones or UAV's (Unmanned Aerial Vehicles), an intelligent drone can be equipped with a smart phone containing the proprietary app, in which the intelligent drone can be programmed to fly over miles of remote power lines containing power line monitors. As the intelligent drone equipped with a smart phone containing the proprietary app flies over the power lines, it will transmit a command to any power line monitor within range commanding it to transmit its status data that will be recorded onto the smart phone, along with the time, date, and GPS coordinates of the device. If the power lines are located within a “dead zone” for cell phones, the smart phone app can temporarily store the data and then transmit the data when the intelligent drone is within a cell phone signal, or the smart phone can manually download the stored data when interrogated by a computer containing proprietary software that works in unison with the proprietary app on the smart phone. Although the described patent discusses a proprietary app that can be freely downloaded onto the smart phones of customers of the power company, there will also a power company employee app that contains enhanced features that a customer app will not contain. One of the features on the power company's proprietary app that would not be included on the customer proprietary app would be the ability to manually interrogate a power line monitor. Instead of including a smart phone type module within each power line monitor, a cheaper method would be to utilize a distributed intelligence scheme in which a free app could be downloaded onto a customers smart phone. As the customer drove around town, the smart phone would acquire transmitted bluetooth signals and then transmit the power line monitors status information through either WiFi or a cellular connection. The transmitted information would include the time and date that the information was acquired from the power line monitor as well as the GPS coordinates of the power line monitor. This information would be transmitted to the power company or to a third party monitoring company that will send important information to the power company.

As an incentive to entice people to download the free app to their smart phone, the power company could give the person a small rebate on their bill. In addition to the proprietary app that will be used for customers, a first responder app will be used for police, fire, or paramedics. This app will have more detained information than the customer app and it will allow for an interactive polling that will allow the first responder to interrogate any power line monitor within range to assess its status. The power company can also send alerts to first responder proprietary apps that will give real time, or near real time updates of power line conditions.

### ADDITIONAL FEATURES OF DISCLOSED INVENTION

The disclosed invention, owing to the perch afforded by an overhead powerline, provides the following new and useful features. The addition of a microphone to the sensor package with on-board memory, can allow the recording and storage of select audio signals. For example, if a gunshot transpired in a city, such gunshots having a well-known and established signal spectra, can be triangulated using multiple acoustic receivers within a city. The disclosed invention offers multiple locations for acoustic signal capture, storage, and dissemination of gun shots, police or other emergency vehicles such as those utilizing sirens, motor vehicles with unique acoustical signal spectra to aid in law enforcement location, or even disasters such as local gas explosions. The disclosed invention offers a means by which emergency notification can be effected based on the magnitude, location, signal spectra, or other targeted parameter of such signal is defined by the user, to be reported.

The disclosed invention provides for a system for standoff detection of temperature, wind speed, and humidity data collection, storage, and dissemination for weather and natural disaster reporting.

The disclosed invention offers a means and system for standoff detection, recording, and broadcast of GPS signals, such that in the event of loss of satellite GPS signals, the distributed nodes or individual node of the disclosed invention can serve as a surrogate GPS emitter in times of emergency.

The disclosed invention also provides for a system for standoff video recording, storage, and dissemination useful for isolating criminal or terrorist events, weather, or any other condition where a video image of a given scene at a specific place and time would be of advantage.

The disclosed invention also provides for a system for standoff detection of radioactive alpha, beta, and gamma radiation for natural, man-made, terrorist, or other radioactive background that might pose a threat in the vicinity of the sensor node.

The disclosed invention provides for a system for standoff detection of particulate media in the ambient air such as smoke or other particulate media to afford the ability to monitor smog and to provide early detection of fires.

It will be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A system for the standoff detection of power line hazards comprising:
a ferrite core having a window,
a power line to be monitored passing through the window and forming a first winding,
a second winding passing through the window and having a first and second terminal,
a low pass filter coupled to the second winding and outputting a filtered electrical signal,
a full wave rectifier means coupled to the filtered electrical signal to provide charging current for a backup battery and to provide a filtered bus voltage source,
an RMS to DC converter having a first input connected to the bridge rectifier first input and a second input connected to the bridge rectifier second input, the signal at the rectifier first terminal and second input terminal being characterized as a filtered electrical signal being coupled to the RMS to DC converter inputs, the RMS to DC converter processing the filtered electrical signal to provide
a DC signal,
a MICRO CONTROLLER having a first and second input coupled to receive the DC signal, the MICRO CONTROLLER being programmed to identify a plurality of electrical states and to provide an output for each electrical state identified, and
a SENSOR PACKAGE containing a plurality of sensors selected from a group comprising:
an electrical field detector;
an angular, shock, or motion detector;
an MEMS accelerometer; and a
a three axis spatial attitude detector;
the SENSOR PACKAGE BEING CHARACTERIZED to provide discrete outputs to,
a COMMUNICATIONS MODULE, the communications module being coupled to receive the discrete outputs from the SENSOR PACKAGE and to output discrete alarm signals identifying the defect to a communications link to a responsible service center.

2. The system for the standoff detection of power line hazards of claim 1 wherein the window is further characterized to receive a second power line carrying a return current from the first power line, whereby ampere turn cancellation is obtained.

3. The system for the standoff detection of power line hazards of claim 1 further comprising:
a solar array for producing dc charging current for
a backup battery.

4. The system for the standoff detection of power line hazards of claim 1 wherein the COMMUNICATIONS MODULE is further characterized to provide alert signals to pedestrians selected from the set comprising:
Optical alerts,
acoustical alerts, and
voice synthesis for spoken warnings to area pedestrians

5. The system for the standoff detection of power line hazards of claim 1 wherein the ferrite core is further characterized as being formed to have two halves that are joined around the power line to be monitored.

6. The system for the standoff detection of power line hazards of claim 1 wherein the MICRO CONTROLLER is programmed to identify states selected from the following set of states:
a. presence of a B and E field, and no spatial change in sensor position;
b. loss of B field and presence of E field, no spatial change
c. loss of B and E field, due to a sudden spatial change
d. loss of B field and presence of E field, due to a sudden spatial change, and
e. a transient loss or presence of B & E fields, due to a sudden spatial change or due to intermittent spikes

7. The system for the standoff detection of power line hazards of claim 1 further

8. A system for the standoff detection of power line hazards comprising:
a ferrite core having a window,
a power line to be monitored passing through the window and forming a first winding,
a second winding passing through the window and having a first and second terminal,
a series resistor having a first end, and a second end, the series resistor first end being connected to the second winding first terminal,
a shunt capacitor having a first end and a second end, the shunt capacitor first end being connected to the series resistor second end, the capacitor second end being connected to the second winding second terminal,
a bridge rectifier having a first and second input terminal, a positive output terminal and a negative output terminal, the first input terminal being connected to the series resistor second, the bridge rectifier second input terminal being connected to the capacitor second end,
a low pass filter formed by a second resistor having a first and second end and
a second capacitor having a first and second end, the second resistor first end being connected to the bridge rectifier positive output terminal, the second capacitor first end being connected to the second resistor second end, the second capacitor second end being connected to the bridge rectifier negative output terminal,
an RMS to DC converter having a first input connected to the bridge rectifier first input and a second input connected to the bridge rectifier second input,
the signal at the rectifier first terminal and second input terminal being characterized as a filtered electrical signal being coupled to the RMS to DC converter inputs, the RMS to DC converter processing the filtered electrical signal to provide
a DC signal,
a MICRO CONTROLLER having a first and second input coupled to receive the DC signal, the MICRO CONTROLLER being programmed to identify a plurality of electrical states and to provide an output for each electrical state identified,
a SENSOR PACKAGE containing a plurality of sensors selected from a group comprising:
an electrical field detector;
an angular, shock, or motion detector;
an MEMS accelerometer; and a
a three axis spatial attitude detector;
the SENSOR PACKAGE BEING CHARACTERIZED to provide discrete outputs to,
a COMMUNICATIONS MODULE, the communications module being coupled to receive the discrete outputs from the SENSOR PACKAGE and to output discrete alarm signals identifying the defect to a communications link to a responsible service center.

9. The system for the standoff detection of power line hazards of claim 8 wherein the window is further characterized to receive a second power line carrying a return current from the first power line, whereby ampere turn cancellation is obtained.

10. The system for the standoff detection of power line hazards of claim 9 further comprising:
a solar array for producing dc charging current for
a backup battery.

11. The system for the standoff detection of power line hazards of claim 8 wherein the COMMUNICATIONS MODULE is further characterized to provide alert signals to pedestrians selected from the set comprising:
Optical alerts,
acoustical alerts, and
voice synthesis for spoken warnings to area pedestrians

12. The system for the standoff detection of power line hazards of claim 8 wherein the ferrite core is further characterized as being formed to have two halves that are joined around the power line to be monitored.

13. The system for the standoff detection of power line hazards of claim 8 wherein the MICRO CONTROLLER is programmed to identify states selected from the following set of states:
a. presence of a B and E field, and no spatial change in sensor position;
b. loss of B field and presence of E field, no spatial change
c. loss of B and E field, due to a sudden spatial change
d. loss of B field and presence of E field, due to a sudden spatial change, and
e. a transient loss or presence of B & E fields, due to a sudden spatial change or due to intermittent spikes

14. A system for the standoff detection of power line hazards comprising:
a split ferrite core having a first and second half, the split ferrite core forming a window when the first half of the split ferrite core is joined with the second half of the split ferrite core,
a power line to be monitored passing through the window and forming a first winding,
a second winding passing through the window and having a first and second terminal,
a low pass RC filter coupled to the second winding and outputting a filtered electrical signal,
a full wave rectifier means coupled to the filtered electrical signal to provide charging current for a backup battery and to provide a filtered bus voltage source,
an RMS to DC converter having a first input connected to the bridge rectifier first input and a second input connected to the bridge rectifier second input,
the signal at the rectifier first terminal and second input terminal being characterized as a filtered electrical signal being coupled to the RMS to DC converter inputs, the RMS to DC converter processing the filtered electrical signal to provide
a DC signal,
a MICRO CONTROLLER having a first and second input coupled to receive the DC signal, the MICRO CONTROLLER being programmed to identify a plurality of electrical states and to provide an output for each electrical state identified,
a SENSOR PACKAGE containing a plurality of sensors selected from a group comprising:
an electrical field detector;
an angular, shock, or motion detector;
an MEMS accelerometer; and a
a three axis spatial attitude detector;
the SENSOR PACKAGE BEING CHARACTERIZED to provide discrete outputs to,
a COMMUNICATIONS MODULE, the communications module being coupled to receive the discrete outputs from the SENSOR PACKAGE and to output discrete alarm signals identifying the defect to a communications link to a responsible service center.

15. The system for the standoff detection of power line hazards of claim 14 wherein the window is further characterized to receive a second power line carrying a return current from the first power line, whereby amper turn cancelation is obtained.

16. The system for the standoff detection of power line hazards of claim 14 further comprising:
a solar array for producing dc charging current for a backup battery.

17. The system for the standoff detection of power line hazards of claim 14 wherein the COMMUNICATIONS MODULE is further characterized to provide alert signals to pedestrians selected from the set comprising:
Optical alerts,
acoustical alerts, and
voice synthesis for spoken warnings to area pedestrians

18. The system for the standoff detection of power line hazards of claim 14 wherein the MICRO CONTROLLER is programmed to identify states selected from the following set of states:
a. presence of a B and E field, and no spatial change in sensor position;
b. loss of B field and presence of E field, no spatial change
c. loss of B and E field, due to a sudden spatial change
d. loss of B field and presence of E field, due to a sudden spatial change, and
a transient loss or presence of B & E fields, due to a sudden spatial change or due to intermittent spikes
